(19) United States
(12) Patent Application Publication
(10) Pub. No.: US 2004/0063284 A1
(43) Pub. Date: Apr. 1, 2004

(54) Scalable dielectric

(75) Inventors: Cetin Kaya, Plano, TX (US); Men Chee Chen, Dallas, TX (US); Kemal Tamer San, Plano, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/675,167

(22) Filed: Sep. 30, 2003

Related U.S. Application Data
(62) Division of application No. 10/008,695, filed on Nov. 8, 2001.
(60) Provisional application No. 60/259,319, filed on Dec. 31, 2000.
(60) Provisional application No. 60/297,407, filed on Jun. 11, 2001.

(51) Int. Cl. H01L 21/336; H01L 21/3205; H01L 29/788

(52) U.S. Cl. 438/261; 438/257; 438/593; 257/315

(57) ABSTRACT

An interpoly dielectric is formed using only a single layer of oxide and a single layer of nitride to allow a reduction in thickness. The nitride is thermally grown on silicon in a nitrogen environment to maintain a high quality layer, while the oxide is deposited by LPCVD.

### BACKGROUND AND SUMMARY OF THE INVENTION

The present invention relates to integrated circuit structures and fabrication methods.

Background: Processing of Flash Memories

FIG. 3 is a simplified conceptual diagram of a Flash memory, and gives some idea of the layout of such a memory on chip. The array of memory cells takes up the largest portion of the chip, while decoder and logic circuitry are placed generally towards the edges of the array. Generally, the processing flow for the FLASH memory array, which has to hold a value for a long time, is different than the processing flow for the CMOS logic circuitry. Thus, when forming the chip, the two processes must be integrated carefully, often with masks or protective layers for areas which must not be disturbed by current or subsequent processing. However, adding additional steps or another mask to a process can ultimately cost millions of dollars, so every step of the process is carefully scrutinized to be sure that it does its job effectively and does not adversely affect other steps.

Background: Dielectrics in Non-Volatile Memory

It is well known that the general trend of integrated circuits and memory devices has been, for a number of years, toward ever smaller and ever faster devices. To achieve this objective, traditional methods and materials are being pushed to their physical limits, while newer materials are explored and newer techniques are being developed. In non-volatile memories, such as FLASH, this means that storage devices are closer together, intensifying problems such as leakage and unintentional capacitances. Thus, while it is necessary to make dielectrics thinner, it is also necessary to assure that they are more dependable.

In FLASH memories, a very thin dielectric layer is used to separate the polysilicon layer which forms the floating gates from the polysilicon layer which forms the control gates. In recent years, this thin dielectric is generally formed of three separate, very thin, dielectrics, namely an oxide, nitride, oxide (ONO), generally silicon oxide and silicon nitride. Generally, the thicknesses are about 60 Δ for each of the three layers.

The basic requirements for this interpoly dielectric are that it must (1) have low leakage currents for data retention, and (2) must act as an oxidation barrier during gate oxidations so that it is possible to independently optimize interpoly oxide and CMOS oxide thicknesses, and (3) have minimum change in the capacitance due to the introduction of the oxidation barrier. However, it is becoming hard to scale these three layers down further. It would be more desirable to have a one-level or two-level interpoly dielectric if it could fulfill the above stated requirements, as fewer layers can be made thinner.

Single-layer oxide dielectrics have been used between the polysilicon layers in the past, but because they were thermally grown, they had higher leakage currents than the ONO stack, where the components have generally been laid down by low pressure chemical vapor deposition (LPCVD). Another problem with these older, single-layer oxide dielectrics was that, since they overlaid polysilicon in at least some areas, thermal oxidations performed to grow oxides in other portions of the chip would also cause further oxidation under these interpoly dielectrics, an undesirable effect.

Forming Thinner Dielectrics for Non-Volatile Memory

The present application discloses a dielectric which can be made thinner than previous attempts. Rather than a three-layer ONO dielectric, it is disclosed to use a two-layer dielectric composed of nitride and oxide. The oxide is thicker than a single layer of oxide in the ONO, but thinner than the two oxide layers together. The nitride layer is thinner than previously formed, using more controllable methods, giving a total reduction in thickness of the dielectric layer.

Advantages of the disclosed methods and structures, in various embodiments, can include one or more of the following:

dielectric layer is thinner than previously possible;

dielectric layer is very high quality;

dielectric includes an oxidation barrier;

leakage currents are low;

can be done with few changes in current process flow.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIGS. 1A-C show the formation of one embodiment of the disclosed dielectric separating two polysilicon layers.

FIG. 2 shows an alternate embodiment of the disclosed dielectric.

FIG. 3 is an exemplary diagram of a flash memory.

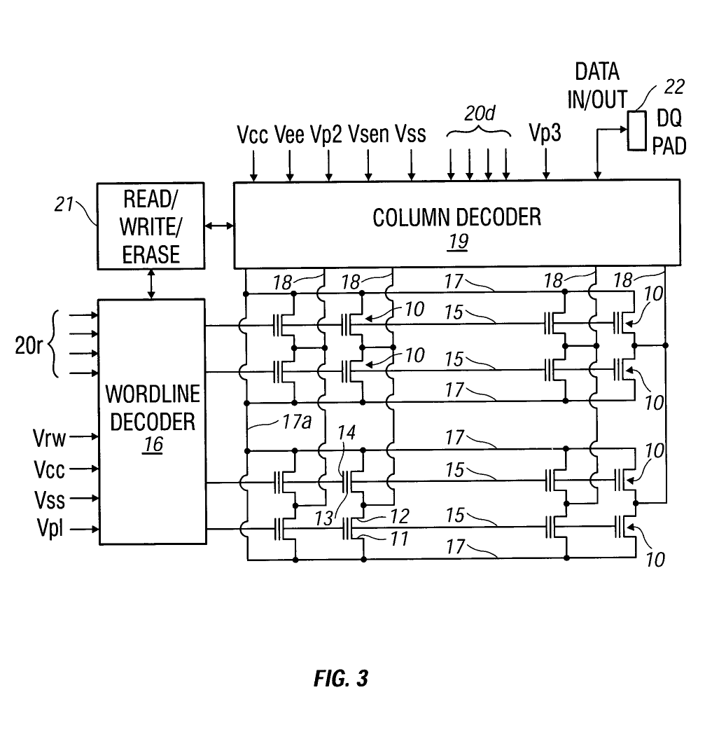

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

First embodiment: Oxide Over Nitride

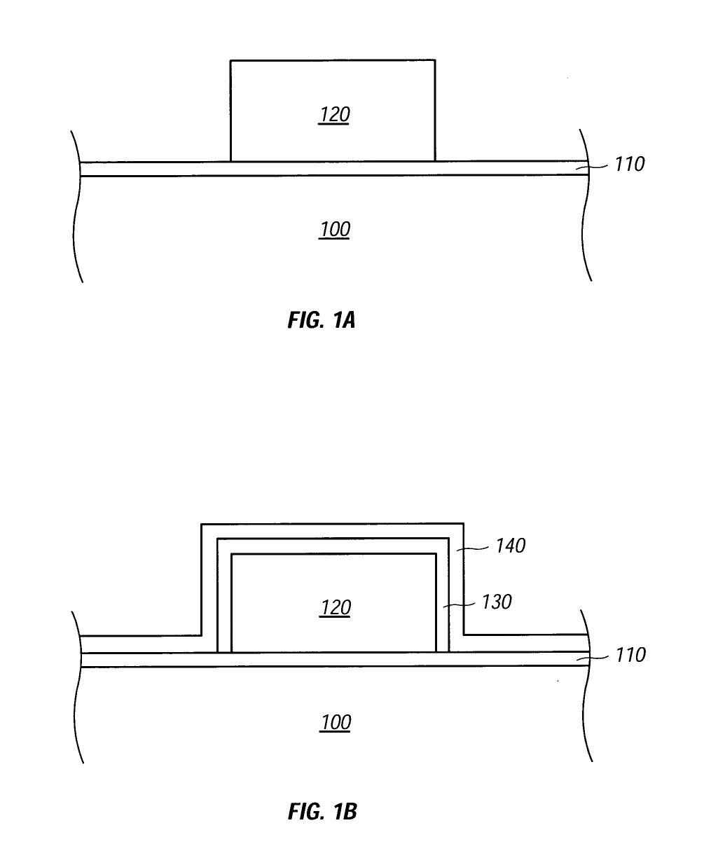

One method of forming the disclosed dielectric in processing a FLASH array will now be discussed. There are many methods of forming such an array, and it is to be understood that the disclosed dielectric layer can be used on many variations on this process. Nor is this process meant to be an exhaustive discussion of the process of forming a FLASH array, as many steps are conventional and do not need to be discussed in detail. For instance, doping of the semiconductor regions is not discussed, although it is an important part of the process flow. FIG. 1A shows a cross-section of a chip on which an exemplary FLASH array is being formed. A number of steps have already been performed. Tunnel oxide 110 is formed on the surface of the silicon wafer 100. A layer of polysilicon 120 is deposited, masked, and etched to form the floating gates.

It is at this point that the disclosed interpoly dielectric is formed, as shown in FIG. 1B. It has been found to be difficult to deposit nitride by LPCVD to significantly less than 60 Δ without defects. For that reason, the nitride film should not be LPCVD-deposited. Rather, in the presently preferred embodiment, thermal nitride 130 is grown directly on the surface of the polysilicon 120 by rapid thermal nitridation (RTP), using a furnace and a nitrogen atmosphere. In the presently preferred embodiment, a temperature of 1150EC is used for 10 seconds to produce a silicon nitride layer 20-30 Δ thick.

After the nitride layer is formed, a layer of oxide 140 is then deposited by LPCVD to a thickness of about 100 Δ. This is somewhat thicker than the oxide layer in the ONO dielectric, but less than the two layers of oxide together. Overall, the dielectric thickness is reduced from about 180 Δ to 120-130 Δ.

Once the disclosed dielectric is completed, a subsequent layer of polysilicon 150 can be deposited and etched to form the control gate. Additional dielectric layers and contacts to the transistors are formed.

Alternate Embodiment: Nitridation After Oxide Deposition

In an alternative embodiment, the order in which the interpoly dielectric layers are formed is reversed, so that oxide layer 140 is first deposited by LPCVD over polysilicon layer 120. This is followed by rapid thermal processing in a nitrogen environment, causing nitridation of the underlying polysilicon layer 120 by diffusion through the oxide layer 140, forming nitride layer 130.

Alternate Embodiment: Thermal Nitridation Before Floating Gate Etched

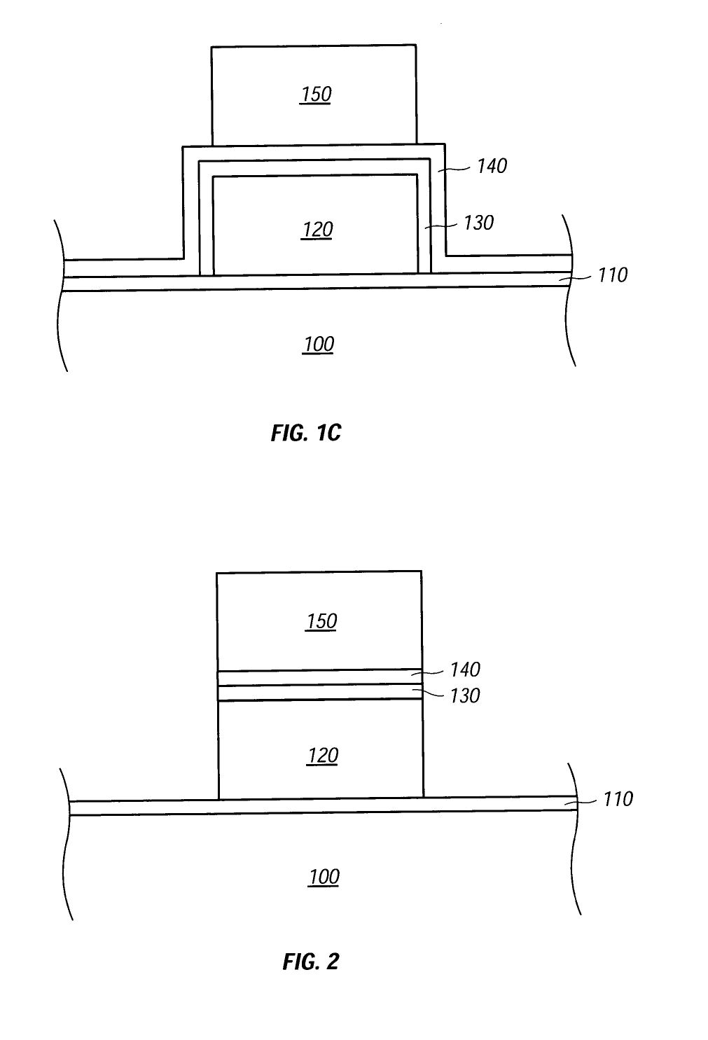

The thermal nitridation step can also be done after the first polysilicon layer is deposited, but before it is etched, seen in FIG. 2. However, this method is less desirable, as it does not achieve capacitances as high as the method above.

Alternate Embodiment: HSG Polysilicon

In a further alternate embodiment, the polysilicon layers can be hemispherical grain (HSG) polysilicon to increase the capacitance two to three times.

According to a disclosed class of innovative embodiments, there is provided: An integrated circuit structure, comprising: a first layer of silicon and a second layer of silicon, said first and second layers of silicon being separated, in at least some areas, only by a dielectric layer; wherein said dielectric layer consists only of a single layer of oxide and a single layer of nitride.

According to another disclosed class of innovative embodiments, there is provided: A FLASH memory integrated circuit structure, comprising: a floating gate; a control gate at least partially overlying said floating gate; wherein said floating gate and said control gate are separated solely by a dielectric layer consisting of a single layer of oxide and a single layer of nitride.

According to another disclosed class of innovative embodiments, there is provided: A fabrication method, comprising the steps of: forming a first layer of silicon at least partially overlying a substantially monolithic body of semiconductor material; forming a layer of nitride at least partially overlying said first layer of silicon; forming a layer of oxide at least partially overlying said first layer of silicon; after said steps of forming said layer of nitride and forming said layer of oxide, but prior to performing any other steps, forming a second layer of silicon at least partially overlying said layer of oxide, said layer of nitride, and said first layer of silicon; wherein only two layers are present between said first layer of silicon and said second layer of silicon.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

For example, if defect levels can be corrected, LPCVD nitride can be an acceptable alternative to growing silicon nitride.

For another example, while the specification refers to polysilicon, this dielectric layer can also be formed between two layers containing monocrystalline silicon, polysilicon, or amorphous silicon, or any combination of these layers.

What is claimed is:

1. An integrated circuit structure, comprising:
a first layer of silicon and a second layer of silicon, said first and second layers of silicon being separated, in at least some areas, only by a dielectric layer;
wherein said dielectric layer consists only of a single layer of oxide and a single layer of nitride.

2. The integrated circuit of claim 1, wherein said first and said second layers of silicon are polysilicon.

3. The integrated circuit of claim 1, wherein said layer of oxide was deposited by LPCVD.

4. The integrated circuit of claim 1, wherein said layer of nitride was thermally grown.

5. The integrated circuit of claim 1, wherein said layer of oxide overlies said layer of nitride.

6. A FLASH memory integrated circuit structure, comprising:
a floating gate;
a control gate at least partially overlying said floating gate;
wherein said floating gate and said control gate are separated solely by a dielectric layer consisting of a single layer of oxide and a single layer of nitride.

7. The integrated circuit of claim 6, wherein said first and said second layers of silicon are polysilicon.

8. The integrated circuit of claim 6, wherein said layer of oxide was deposited by LPCVD.

9. The integrated circuit of claim 6, wherein said layer of nitride was thermally grown.

10. The integrated circuit of claim 6, wherein said layer of oxide overlies said layer of nitride.

11. A fabrication method, comprising the steps of:
forming a first layer of silicon at least partially overlying a substantially monolithic body of semiconductor material;
forming a layer of nitride at least partially overlying said first layer of silicon;
forming a layer of oxide at least partially overlying said first layer of silicon;
after said steps of forming said layer of nitride and forming said layer of oxide, but prior to performing any other steps, forming a second layer of silicon at least partially overlying said layer of oxide, said layer of nitride, and said first layer of silicon;
wherein only two layers are present between said first layer of silicon and said second layer of silicon.

12. The method of claim 11, wherein said layer of oxide is formed before said layer of nitride.

13. The method of claim 11, wherein said layer of nitride is formed before said layer of oxide.

14. The method of claim 11, wherein said layer of oxide is deposited by LPCVD.

15. The method of claim 11, wherein said layer of nitride is thermally grown.
